(19) United States
(12) Patent Application Publication
(10) Pub. No.: US 2014/0322901 A1
(43) Pub. Date: Oct. 30, 2014

(54) SEMICONDUCTOR NANOCRYSTALS, METHOD FOR PREPARING, AND PRODUCTS

(71) Applicant: QD VISION, INC., LEXINGTON, MA (US)

(72) Inventors: DIYUN HUANG, FREMONT, CA (US); CHUNMING WANG, ACTON, MA (US); ZHIMING WANG, PORT LAVACA, TX (US); JONATHAN S. STECKEL, CARLISLE, MA (US)

(73) Assignee: QD VISION, INC., LEXINGTON, MA (US)

(21) Appl. No.: 14/193,839

(22) Filed: Feb. 28, 2014

Related U.S. Application Data
(60) Provisional application No. 61/817,174, filed on Apr. 29, 2013.

(51) Int. Cl. H01L 21/02

(52) U.S. Cl. CPC H01L 21/02658; H01L 21/02601; H01L 21/02628
USPC 438/497

(57) ABSTRACT

A method for preparing semiconductor nanocrystals includes adding a non-protonated surface modification agent to semiconductor nanocrystal cores in a liquid medium to form a mixture; adding one or more precursors for forming a shell including a semiconductor material to the mixture under conditions for forming the shell over at least a portion of an outer surface of the cores, and adding an acid ligand to the mixture after addition of at least a portion of the one or more precursors. Semiconductor nanocrystals, other methods of making semiconductor nanocrystals, compositions and products including semiconductor nanocrystals are also disclosed.

### CLAIM OF PRIORITY

This application claims priority to U.S. Provisional Patent Application No. 61/817,174, filed on 29 Apr. 2013, which is hereby incorporated herein by reference in its entirety for all purposes.

### FEDERALLY SPONSORED RESEARCH OR DEVELOPMENT

This invention was made with Government support under Advanced Technology Program Award No. 70NANB7H7056 awarded by NIST. The United States has certain rights in the invention,

### TECHNICAL FIELD OF THE INVENTION

The present invention relates to the field of nanotechnology and more particularly to semiconductor nanocrystals, methods for preparing semiconductor nanocrystals, and end-use applications including semiconductor nanocrystals.

### SUMMARY OF THE INVENTION

The present invention relates to methods for preparing semiconductor nanocrystals, semiconductor nanocrystals prepared thereby, and products including the foregoing semiconductor nanocrystals,

In accordance with one aspect of the present invention, there is provided a method for preparing semiconductor nanocrystals, the method comprising: adding a non-protonated surface modification agent to semiconductor nanocrystal cores in a liquid medium to form a mixture; adding one or more precursors for forming a shell comprising a semiconductor material to the mixture under conditions for forming the shell over at least a portion of an outer surface of the cores, and adding an acid ligand to the mixture after addition of at least a portion of the one or more precursors,

In another aspect, protonic or acidic species are not present in the mixture including the semiconductor nanocrystals cores before beginning addition of the one or more precursors.

In another aspect, semiconductor nanocrystals cores on which a coating is to be formed are free or substantially free of protonic species. For example, the semiconductor nanocrystal cores can be formed in the absence of protonic species or proton-generating species, protonic species can be removed or substantially completely removed from the semiconductor nanocrystal cores prior to providing a coating thereon.

In a preferred aspect, addition of acid ligand is initiated after completion of the addition of the one or more precursors.

Optionally, one or more non-acid ligands can be further included in the mixture before addition of the precursors, during addition of the precursors, and/or following addition of the precursors.

The method of the present invention can be particularly advantageous in overcoating semiconductor nanocrystals cores comprising a semiconductor material comprising one or more elements of Group IIIA of the Periodic Table of Elements and one or more elements of Group VA of the Periodic Table of Elements.

Overcoated semiconductor nanocrystals in accordance with the present invention can demonstrate improved solution quantum yield, improved particle size distribution, and/or reduced blue shift of the peak emission wavelength of the overcoated nanocrystal.

As used herein, “non-protonated surface modification agent” refers to a non-protonated derivative of an oxyacid, such as a carboxylic acid ester, carboxylic acid anhydride, inorganic oxyacid ester, organic substituted inorganic oxyacid anhydride. While not wishing to be bound by theory, it is believed that the non-protonated surface modification agent modifies the surface of the semiconductor nanocrystal cores overcoated in the presence thereof, the nature of the modification not being fully appreciated. For example, such modification may include very mild etching of the semiconductor nanocrystal surface, with such mild etching not resulting in an appreciable blue shift of the semiconductor nanocrystal emission wavelength. In various aspects, the peak emission wavelength of a semiconductor nanocrystals core overcoated by a method taught herein does not blue shift by more than 20 nm, e.g., not more than 15 nm, not more than 10 nm, not more than 5 nm. Such blue shift can be determined, for example, by comparing the emission of a semiconductor nanocrystal core before and after overcoating.

Examples of particular non-protonated surface modification agents for use in the method taught herein, include, but are not limited to, carboxylic acid esters, carboxylic acid anhydrides, phosphonic acid esters, phosphonic acid anhydrides, other non-protonated chemical derivatives and/or chemical equivalents thereof.

The term “carboxylic acid ester” refers to a compound represented by the formula

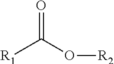

(also written herein as R₁CO₂R₂), where R₁ and R₂ are independently a substituted or unsubstituted aliphatic group (e.g., alkyl) or aromatic group (e.g., aryl), which groups can further include one or more heteroatoms). Carboxylic acid esters further include chemical derivatives of a compound represented by the foregoing formula, and chemical equivalents of any of the foregoing.

The term “carboxylic acid anhydride” refers to a compound represented by the formula

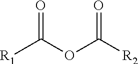

(also written herein as (R₁—C(O)—O—C(O)—R₂)), where R₁ and R₂ are independently a substituted or unsubstituted aliphatic group (e.g., alkyl) or aromatic group (e.g., aryl), which groups can further include one or more heteroatoms). Carboxylic acid anhydrides further include chemical derivatives of a compound represented by the foregoing formula, and chemical equivalents of any of the foregoing.

The term “phosphonic acid ester” refers to a compound represented by one of the following formula:

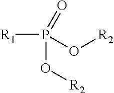

where R₁ and R₂ are independently a substituted or unsubstituted aliphatic group (e.g., alkyl) or aromatic group (e.g., aryl), which groups can further include one or more heteroatoms);

or

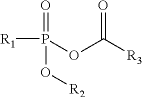

where R₁ and R₂ and R₃ are independently a substituted or unsubstituted aliphatic group (e.g., alkyl) or aromatic group (e.g., aryl), which groups can further include one or more heteroatoms).

Phosphonic acid esters further include chemical derivatives of the compounds represented by the foregoing formulae, and chemical equivalents of any of the foregoing.

The term “phosphonic acid anhydride” refers to a compound represented by the formula

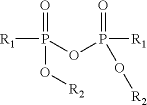

where R₁ and R₂ are independently a substituted or unsubstituted aliphatic group (e.g., alkyl) or aromatic group (e.g., aryl), which groups can further include one or more heteroatoms). Phosphonic acid anhydrides further include chemical derivatives of a compound represented by the foregoing formula, and chemical equivalents of any of the foregoing.

Examples of an R₁, R₂, and/or R₃ aromatic group in the above formulae include, but are not limited to, phenyl, benzyl, naphthyl, tolyl, anthracyl, nitrophenyl, or halophenyl groups. Examples also include heteroaryl groups, including but are not limited to, an aryl group with one or more heteroatoms in the ring, for instance furyl, pyridyl, pyrrolyl, phenanthryl. Examples of an R₁, R₂, and/or R₃ aliphatic groups in the above formulae include, but are not limited to, a straight or branched C₁₋₂₀ hydrocarbon chain, that can include at least one double bond, at least one triple bond, or at least one double bond and one triple bond and/or can be interrupted by —O—, —S—, —N(Rₐ)—, —N(Rₐ)—C(O)—O—, —O—C(O)—N(Rₐ)—, —N(Rₐ)—C(O)—N(R_{b})—, —O—C(O)—O—, —P(Rₐ)—, or —P(O)(Rₐ)—, wherein each of Rₐ and R_{b} independently, is hydrogen, alkyl, alkenyl, alkynyl, alkoxy, hydroxylalkyl, hydroxyl, or haloalkyl. In certain embodiments, the aryl group is a substituted or unsubstituted cyclic aromatic group; examples of an aryl group include phenyl, benzyl, naphthyl, tolyl, anthracyl, nitrophenyl, or halophenyl. Examples of aryl groups also include heteroaryl groups, including, but not limited to, an aryl group with one or more heteroatoms in the ring, for instance furyl, pyridyl, pyrrolyl, phenanthryl.

In accordance with another aspect of the present invention, there is provided a semiconductor nanocrystal prepared by a method described herein.

In accordance with another aspect of the present invention, there is provided a composition including a semiconductor nanocrystal prepared by a method described herein. A composition can further include a host material. A composition can further include one or more additives selected based on the end-use application in which the composition is to be used.

In accordance with another aspect of the present invention, there is provided a light emitting device including a semiconductor nanocrystal prepared by a method described herein.

The foregoing, and other aspects and embodiments described herein all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### DETAILED DESCRIPTION OF THE INVENTION

For a better understanding of the present invention, together with advantages and capabilities thereof, reference is made to the following disclosure.

Semiconductor nanocrystals are nanometer sized semiconductor particles that can have optical properties arising from quantum confinement. Semiconductor nanocrystals can have various shapes, including, but not limited to a sphere, rod, disk, other shapes, and mixtures of various shaped particles. The particular composition(s), structure, and/or size of a semiconductor nanocrystal can be selected to achieve the desired wavelength of light to be emitted from the semiconductor nanocrystal upon stimulation with a particular excitation source. Semiconductor nanocrystals may be tuned to emit light across the spectrum, e.g., ultraviolet, visible, or infra-red regions, by changing their size. See C. B. Murray, C. R. Kagan, and M. G. Bawendi, Annual Review of Material Sci., 2000, 30: 545-610 hereby incorporated by reference in its entirety. The narrow FWHM of semiconductor nanocrystals can result in saturated color emission. The broadly tunable, saturated color emission over the entire visible spectrum of a single material system is unmatched by any class of organic chromophores (see, for example, Dabbousi et al., J. Phys. Chem. 101, 9463 (1997), which is incorporated by reference in its entirety). A monodisperse population of semiconductor nanocrystals will emit light spanning a narrow range of wavelengths.

The present method relates to a method for preparing a semiconductor nanocrystal including a semiconductor nanocrystal core and including a shell over at least a portion of an outer surface of the core (also referred to as a core/shell semiconductor nanocrystal.) A shell can include one or more semiconductor materials. A shell can further comprise one or more layers, each of which can comprise one or more semiconductor materials. The composition of each layer included in a shell can be the same as, or different from, that of an adjacent layer. (Semiconductor nanocrystals are also referred to, in the art, as quantum dots.)

In general, semiconductor nanocrystals can have an average particle size in a range from about 1 to about 1000 nanometers (nm), and preferably in a range from about 1 to about 100 nm. In certain embodiments, semiconductor nanocrystals have an average particle size in a range from about 1 to about 20 nm (e.g., such as about 2, 3, 4, 5, 6, 7, 8, 9, 10, 11, 12, 13, 14, 15, 16, 17, 18, 19, or 20 nm). In certain embodiments, semiconductor nanocrystals have an average particle size in a range from about 1 nm to about 20 nm or about 1 nm to about 10 nm. Semiconductor nanocrystals can have an average diameter less than about 150 Angstroms (Å). In certain embodiments, semiconductor nanocrystals having an average diameter in a range from about 12 to about 150 Å can be particularly desirable. However, depending upon the composition, structure, and desired emission wavelength of the semiconductor nanocrystal, the average diameter may be outside of these ranges.

According to one aspect of the present invention, there is provided a method for preparing semiconductor nanocrystals, comprising: adding a non-protonated surface modification agent to semiconductor nanocrystal cores in a liquid medium to form a mixture; adding one or more precursors for forming a shell comprising a semiconductor material to the mixture under conditions for forming the shell over at least a portion of an outer surface of the cores, and adding an acid ligand to the mixture after addition of at least a portion of the one or more precursors.

A semiconductor nanocrystal core can comprise one or more a semiconductor materials, typically inorganic semiconductor materials. Examples of semiconductor materials that can be included in semiconductor nanocrystals include, but are not limited to, a Group IV element, a Group II-VI compound, a Group II-V compound, a Group III-VI compound, a Group III-V compound, a Group IV-VI compound, a Group compound, a Group II-IV-VI compound, and/or a Group II-IV-V compound, an alloy including any of the foregoing, and/or a mixture including any of the foregoing, including ternary and quaternary mixtures or alloys, with Group I referring to Group IB (e.g., Cu, Ag, Au) of the Periodic Table, Group II referring to Group BB (e.g., Zn, Cd, Hg) of the Periodic Table, Group III referring to Group IIIA (e.g., Al, Ga, In, TI) of the Periodic Table, Group IV (e.g., Si, Ge) of the Periodic Table, Group V referring to Group VA (N, P, As, Sb) of the Periodic Table, Group VI referring to Group VIA (e.g., O, S, Se, Te) of the Periodic Table.

A non-limiting list of examples include ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TIN, TlP, TIAs, TlSb, PbO, PbS, PbSe, PbTe, Ge, Si, an alloy including any of the foregoing, and/or a mixture including any of the foregoing, including ternary and quaternary mixtures or alloys.

Semiconductor nanocrystals cores can be commercially purchased or can be prepared by known methods. One example of a method of making semiconductor nanocrystal cores (also referred to as quantum dot cores) is a colloidal growth process. For example, for a semiconductor nanocrystal core comprising an inorganic semiconductor material represented by the formula MX, where M represents, for example, one or more metals, and X represents, for example, one or more Group VA and/or Group VIA elements, colloidal growth can occur by injection of one or more M donors and one or more X donors into a hot coordinating solvent, wherein the M and X donors are selected to achieve the desired MX semiconductor material. One example of a preferred method for preparing monodisperse semiconductor nanocrystal cores comprises pyrolysis of organometallic reagents, such as dimethyl cadmium, injected into a hot, coordinating solvent. This permits discrete nucleation and results in the controlled growth of macroscopic quantities of semiconductor nanocrystal cores. The injection produces a nucleus that can be grown in a controlled manner to form a semiconductor nanocrystal core. The reaction mixture can be gently heated to grow and anneal the semiconductor nanocrystal core. Both the average size and the size distribution of the semiconductor nanocrystal cores in a sample can depend on the growth temperature. Resulting semiconductor nanocrystal cores are members of a population of semiconductor nanocrystal cores. As a result of the discrete nucleation and controlled growth, the population of semiconductor nanocrystal cores that can be obtained has a narrow, monodisperse distribution of diameters. The monodisperse distribution of diameters can also be referred to as a “size.” Preferably, a monodisperse population of particles includes a population of particles wherein at least about 60% of the particles in the population fall within a specified particle size range. A population of monodisperse particles preferably deviate less than 15% rms (root-mean-square) in diameter and more preferably less than 10% rms and most preferably less than 5%.

The liquid medium can comprise one or more coordinating solvents, weakly coordinating solvents, and or non-coordinating solvents.

In certain aspects, a liquid medium comprising a coordinating solvent can be desirable. A coordinating solvent is a compound having a donor lone pair, for example, a lone electron pair available to coordinate to a surface of a semiconductor nanocrystal. Solvent coordination can stabilize the growing of semiconductor nanocrystal cores or growing of an overcoating thereon.

Examples of suitable non-coordinating solvents include, but are not limited to, squalane, octadecane, or any other saturated hydrocarbon molecule.

In certain aspects, the liquid medium is non-protic, e.g., does not include free H⁺ which can react with the non-protonated surface modification agent to create an acid form thereof.

Examples of non-protic coordinating solvents include alkyl phosphines, alkyl phosphine oxides, however, other coordinating solvents, such as pyridines, furans, and amines may also be suitable. Additional examples of suitable coordinating solvents include pyridine, tri-n-octyl phosphine (TOP), tri-n-octyl phosphine oxide (TOPO), tributylphosphine, tri(dodecyl)phosphine, dibutyl-phosphite, tributyl phosphite, trioctadecyl phosphite, trilauryl phosphite, tris(tridecyl) phosphite, triisodecyl phosphite, bis(2-ethylhexyl)phosphate, tris(tridecyl) phosphate, hexadecylamine, oleylamine, octadecylamine, bis(2-ethylhexyl)amine, octylamine, dioctylamine, trioctylamine, dodecylamine/laurylamine, didodecylamine tridodecylamine, hexadecylamine, dioctadecylamine, trioctadecylamine, dioctyl ether, diphenyl ether, methyl myristate, octyl octanoate, N-dodecylpyrrolidone (NDP) and hexyl octanoate. In certain embodiments, technical grade TOPO can be used.

As will be appreciated by the skilled artisan, in aspects of the invention calling for a non-protic environment, use of acids as a solvent is preferably avoided.

The method is preferably carried out in an inert atmosphere. The method is more preferably carried out in a controlled atmosphere (substantially free of moisture and air).

As described above, a non-protonated surface modification agent refers to a non-protonated derivative of an oxyacid, such as a carboxylic acid ester, carboxylic acid anhydride, inorganic oxyacid ester, organic substituted inorganic oxyacid anhydride.

While not wishing to be bound by theory, it is believed that the non-protonated surface modification agent modifies the surface of the semiconductor nanocrystal cores overcoated in the presence thereof, the nature of the modification not being fully appreciated. For example, such modification may include very mild etching of the semiconductor nanocrystal surface, with such mild etching not resulting in an appreciable blue shift of the semiconductor nanocrystal emission wavelength. In various aspects, the emission wavelength of a semiconductor nanocrystal core overcoated by a method taught herein does not blue shift by more than 20 nm, e.g., not more than 15 nm, not more than 10 nm, not more than 5 nm. Such blue shift can be determined, for example, by comparing the emission of a semiconductor nanocrystal core before and after overcoating.

Examples of particular non-protonated surface modification agents for use in the method taught herein, include, but are not limited to, carboxylic acid esters, carboxylic acid anhydrides, phosphonic acid esters, phosphonic acid anhydrides, other non-protonated chemical derivatives and/or chemical equivalents thereof.

As described above, the term “carboxylic acid ester” refers to a compound represented by the formula

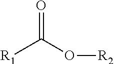

(also written herein as R₁CO₂R₂), where R₁ and R₂ are independently a substituted or unsubstituted aliphatic group (e.g., alkyl) or aromatic group (e.g., aryl), which groups can further include one or more heteroatoms). Carboxylic acid esters further include chemical derivatives of a compound represented by the foregoing formula, and chemical equivalents of any of the foregoing.

As further described above, the term “carboxylic acid anhydride” refers to a compound represented by the formula

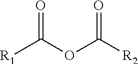

(also written herein as (R₁—C(O)—O—C(O)—R₂)), where R₁ and R₂ are independently a substituted or unsubstituted aliphatic group (e.g., alkyl) or aromatic group (e.g., aryl), which groups can further include one or more heteroatoms). Carboxylic acid anhydrides further include chemical derivatives of a compound represented by the foregoing formula, and chemical equivalents of any of the foregoing.

As yet further described above, the term “phosphonic acid ester” refers to a compound represented by one of the following formula:

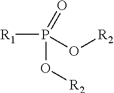

where R₁ and R₂ are independently a substituted or unsubstituted aliphatic group (e.g., alkyl) or aromatic group (e.g., aryl), which groups can further include one or more heteroatoms);

or

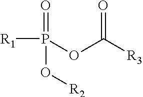

where R₁ and R₂ and R₃ are independently a substituted or unsubstituted aliphatic group (e.g., alkyl) or aromatic group (e.g., aryl), which groups can further include one or more heteroatoms).

Phosphonic acid esters further include chemical derivatives of the compounds represented by the foregoing formulae, and chemical equivalents of any of the foregoing.

As still further described above, the term “phosphonic acid anhydride” refers to a compound represented by the formula

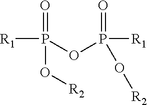

where R₁ and R₂ are independently a substituted or unsubstituted aliphatic group (e.g., alkyl) or aromatic group (e.g., aryl), which groups can further include one or more heteroatoms). Phosphonic acid anhydrides further include chemical derivatives of a compound represented by the foregoing formula, and chemical equivalents of any of the foregoing.

Examples of an R₁, R₂, and/or R₃ aromatic group in the above formulae include, but are not limited to, phenyl, benzyl, naphthyl, tolyl, anthracyl, nitrophenyl, or halophenyl groups. Examples also include heteromyl groups, including but are not limited to, an aryl group with one or more heteroatoms in the ring, for instance furyl, pyridyl, pyrrolyl, phenanthryl. Examples of an R₁, R₂, and/or R₃ aliphatic groups in the above formulae include, but are not limited to, a straight or branched C₁₋₂₀ hydrocarbon chain, that can include at least one double bond, at least one triple bond, or at least one double bond and one triple bond and/or can be interrupted by —O—, —S—, —N(Rₐ)—, —N(Rₐ)—C(O)—O—, —O—C(O)—N(Rₐ)—, —N(Rₐ)—C(O)—N(R_{b})—, —O—C(O)—O—, —P(Rₐ)—, or —P(O)(Rₐ)—, wherein each of Rₐ and R_{b} independently, is hydrogen, alkyl, alkenyl, alkynyl, alkoxy, hydroxylalkyl, hydroxyl, or haloalkyl. In certain embodiments, the aryl group is a substituted or unsubstituted cyclic aromatic group; examples of an aryl group include phenyl, benzyl, naphthyl, tolyl, anthracyl, nitrophenyl, or halophenyl. Examples of aryl groups also include heteroaryl groups, including, but not limited to, an aryl group with one or more heteroatoms in the ring, for instance furyl, pyridyl, pyrrolyl, phenanthryl.

A non-protonated surface modification agent can comprise a single non-protonated surface modification agent or a mixture of two or more non-protonated surface modification agents.

The non-protonated surface modification agent can be added to the mixture as a single addition or as a series of periodic additions. If two or more non-protonated surface modification agents are added, they can be added as a mixture or separately. If separately, such separate additions may be carried out simultaneously, sequentially, or in an alternating manner. Additions may also be made in other various manners that may be determined to be desirable by the skilled artisan.

In one aspect, the non-protonated surface modification agent can be added to the mixture in a molar amount in a range from about ¼ A of the number of moles of semiconductor nanocrystal cores included in the mixture (based on the semiconductor material composition of the core without regard to ligand(s)) to about three times the number of moles of semiconductor nanocrystal cores included in the mixture, e.g., the non-protonated surface modification agent can be added to the mixture in a molar amount from about 0.5 to about 2 times the number of moles of semiconductor nanocrystal cores included in the mixture can be desirable. Other molar amounts may be determined by the skilled artisan, based on this disclosure, to be useful or desirable.

As discussed herein, a shell can comprise a semiconductor material. The shell can comprise an overcoat including one or more semiconductor materials on at least a portion, and preferably all, of the outer surface of the core. Examples of semiconductor materials that can be included in a shell include, but are not limited to, a Group IV element, a Group II-VI compound, a Group II-V compound, a Group III-VI compound, a Group III-V compound, a Group IV-VI compound, a Group compound, a Group II-IV-VI compound, a Group II-IV-V compound, alloys including any of the foregoing, and/or mixtures including any of the foregoing, including ternary and quaternary mixtures or alloys. Examples of semiconductor materials include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TlAs, TlSb, PbO, PbS, PbSe, PbTe, Ge, Si, an alloy including any of the foregoing, and/or a mixture including any of the foregoing. For example, ZnS, ZnSe or CdS overcoatings can be grown on a semiconductor nanocrystal core.

Non-limiting examples of semiconductor materials include compositions including a chemical element from Group IVA and compositions represented by the general formula MX wherein M comprises at least one metal and X comprises at least one chemical element from Group VA (also referred to as pnictogens) and/or VI (also referred to as chalcogens) of the Period Table. In certain embodiments, the semiconductor material can comprise at three or more different chemical elements. In certain examples, M comprises one or more elements from Group IA (for example, lithium, sodium, rubidium, and cesium), Group IIA (for example, beryllium, magnesium, calcium, strontium, and barium), Group IIB (for example, Zn, Cd, and Hg), Group IIIA (for example, B, Al, Ga, In, and TI), Group IVA (for example, Si, Ge, Sn, and Pb), or the transition metals (for example, Ti, Zr, Hf, V, Nb, Ta, Cr, Mo, W, Mn, Tc, Re, Fe, Co, Ni, Pd, Pt, Rh, and the like). (See, F. A. Cotton et al., Advanced Inorganic Chemistry, 6th Edition, (1999). In certain examples, X comprises one or more elements selected from Group VA (for example, nitrogen, phosphorus, arsenic, antimony, and bismuth) and/or Group VIA (for example, oxygen, sulfur, selenium, and tellurium). Other semiconductor materials suitable for inclusion in the shell, including, but not limited to, other examples of semiconductor materials disclosed elsewhere in the detailed description, can be used. The semiconductor material is preferably an inorganic semiconductor material.

Semiconductor nanocrystal precursors for forming a shell comprising a semiconductor material that can be represented by the formula MX can comprise one or more M donors and one or more X donors that are selected based on the composition of the semiconductor nanocrystal being prepared. In preparing semiconductor nanocrystals that include two or more different metal constituents, a combination of M-donors can be used to provide the two or more different metal constituents for preparing the desired semiconductor nanocrystal. Analogously, in preparing semiconductor nanocrystals that include two or more different X constituents, a combination of X-donors can be used to provide the two or more different X constituents for preparing the desired semiconductor nanocrystal. Alternatively, a single semiconductor nanocrystal precursor including the desired M and X constituents can be used. A semiconductor nanocrystal comprising, for example, a Group IV element can also be prepared from a single semiconductor nanocrystal precursor.

Exemplary semiconductor materials for inclusion in the shell include those having metal from the metal precursors and chalcogen from a chalcogen precursor, for example, including but not limited to, a secondary phosphine chalcogenide or secondary phosphine chalcogenide precursor compound or oxygen-treated tertiary phosphine chalcogenide. Accordingly, exemplary semiconductor materials for inclusion in the shell include those of the formula MX, where M is a metal from a metal donor or metal precursor and X is a compound from an X donor or X precursor which is capable of reacting with the metal donor to form a material with the general formula MX. In certain embodiments, the M donor and the X donor can be moieties within the same molecule.

Exemplary semiconductor materials for inclusion in the shell include those having metal from the M donor and pnictogens from the X donor. Accordingly, exemplary semiconductor materials for inclusion in the shell include those of the formula MX, where M is a metal from a metal donor or metal precursor and X is a compound from an X donor or X precursor which is capable of reacting with the metal donor to form a material with the general formula MX, In certain embodiments, the M donor and the X donor can be moieties within the same molecule.

The M donor or metal precursor can be an inorganic compound, an organometallic compound, or elemental metal.

Metal precursors (or M donors) can constitute a wide range of substances, such as elements (oxidation state 0), covalent compounds, ionic compounds, and/or coordination complexes, that serve as a source for the metal constituent of the resulting semiconductor material. Examples of M donors include, but are not limited to, a metal oxide, a metal carbonate, a metal bicarbonate, a metal sulfate, a metal sulfite, a metal phosphate, metal phosphite, a metal halide, a metal carboxylate, other metal salts, a metal alkoxide, a metal thiolate, a metal amide, a metal imide, a metal alkyl, a metal aryl, a metal coordination complex, a metal solvate, and the like. Other M donors can be readily ascertained by one of ordinary skill in the art.

Examples of metals include cadmium, zinc, magnesium, mercury, aluminum, gallium, indium, thallium, or mixtures. Other metals that can react to form a semiconductor material comprising an inorganic semiconductor compound including a chalcogen and/or pnictogen can also be used.

Exemplary metal precursors include dimethylcadmium, cadmium oleate, trialkyl indium, indium myristate. For example, an M donor or metal precursor can comprise other sources of cadmium, zinc, magnesium, mercury, aluminum, gallium, indium, thallium, lead, germanium or mixtures thereof.

The X donor can comprise a compound capable of reacting with the M donor to form a material with the general formula MX.

The X donor can comprise a chalcogen or chalcogenide donor where X can comprise oxygen, sulfur, selenium, or tellurium, or mixtures thereof. Suitable chalcogenide donors include, but are not limited to, reactive chalcogenide source, such as highly reactive chalcogenide sources such as (TMS)₂Se, (TMS)₂S, H₂S, chalcogenide mixtures such as octadecene-Se, (ODE/Se), octadecene-S (ODE/s), amine-Se, amine-S, oxygen-treated tertiary phosphine chalcogenide and mixtures thereof and secondary phosphine chalcogenides include a secondary phosphine sulfide, a secondary phosphine selenide, a secondary phosphine telluride, or a secondary phosphine oxide, dialkyl phosphine chalcogenides such as diisobutylphosphine selenides, diisobutylphosphine sulfides, diphenylphosphine selenides, diphenylphosphine sulfides or mixtures thereof or mixtures of any of the above.

The X donor can comprise a pnictogen or pnictide donor where X can comprise nitrogen, phosphorus, arsenic, antimony or mixtures thereof. Suitable pnictogen donors include elements, covalent compounds, or ionic compounds that serve as a source for a Group VA element(s) in the resulting semiconductor material. Group VA donors are most often selected from the Group VA elements themselves (oxidation state 0), covalent compounds, or ionic compounds of the group V elements (N, P, As, or Sb). For example, non-limiting examples of phosphorus precursors include P(SiR₃)₃ wherein R=methyl, ethyl, propyl, butyl, pentyl, hexyl, isopropyl, isobutyl, tert-butyl, etc.), and phosphine. Other Group VA precursors can be readily ascertained by one of ordinary skill in the art.

As discussed above, an X donor can comprise a chalcogenide donor and/or a pnictide donor, such as a phosphine chalcogenide, a bis(silyl) chalcogenide, dioxygen, an ammonium salt, or a tris(silyl) pnictide. Suitable X donors include, for example, but are not limited to, dioxygen, bis(trimethylsilyl) selenide ((TMS)₂Se), trialkyl phosphine selenides such as (tri-noctylphosphine) selenide (TOPSe) or (tri-n-butylphosphine) selenide (TBPSe), trialkyl phosphine tellurides such as (tri-n-octylphosphine) telluride (TOPTe) or hexapropylphosphorustriamide telluride (HPPTTe), bis(trimethylsilyl)telluride ((TMS)₂Te), bis(trimethylsilyl)sulfide ((TMS)₂S), a trialkyl phosphine sulfide such as (tri-noctylphosphine) sulfide (TOPS), an ammonium salt such as an ammonium halide (e.g., NH₄Cl), tris(trimethylsilyl) phosphide ((TMS)₃P), tris(trimethylsilyl) arsenide ((TMS)₃As), or tris(trimethylsilyl) antimonide ((TMS)₃Sb). In certain embodiments, the M donor and the X donor can be moieties within the same molecule.

Exemplary shells can comprise zinc sulfide, cadmium zinc sulfide, cadmium zinc selenide. A shell can also comprise other binary, ternary, or quaternary mixtures or alloys selected by the skilled artisan.

A shell can be grown to various thicknesses. Thickness is generally selected to achieve the desired characteristics of the core/shell semiconductor nanocrystal being prepared. Such selection is within the skill of the person of ordinary skill in the relevant art. For example, the shell can have a thickness less than about one monolayer, about one monolayer, or more than about one monolayer. Preferably, the thickness is less than that at which quantum confinement is not achieved. Thickness can be in a range from greater than about 0 to about 20 monolayers. Thickness can be in a range from greater than about 0 to about 10 monolayers. Thickness can be in a range from greater than about 0 to about 5 monolayers. Thickness can be in a range from about 1 to about 5 monolayers. Thickness can be in a range from about 3 to about 5 monolayers. Thickness of more than 20 monolayers can be grown.

The one or more precursors can be added to the mixture for forming the shell in various manners. For example, additions may be made as a single addition or as a series of periodic additions. If two or more precursors are being added, they can be mixed prior to addition. Alternatively, each can be separately added. Separate additions may be carried out simultaneously, sequentially, or in an alternating manner; independently, separate additions can further be made as a single addition or as a series of periodic additions. Other variations may also be determined to be desirable by the skilled artisan.

According to aspects of the present disclosure, the shell can be grown under conditions which include growing the shell at an exemplary reaction temperature between about 140° C. and about 350° C., between about 150° C. and about 300° C., between about 175° C. and about 280° C., between about 200° C. and about 260° C., above about 140° C., above about 160° C., above about 200° C., above about 225° C., above about 250° C., above about 260° C., above about 270° C., above about 275° C., above about 280° C., above about 290° C., above about 300° C., above about 310° C., above about 320° C., and the like.

Addition of the one or more precursors can optionally be initiated before the temperature of the mixture is at the desired reaction temperature.

As discussed above, addition of acid ligands is initiated after at least a portion of the one or more precursors for forming the shell has been added to the mixture.

Example of acid ligands added to the mixture after addition of the one or more shell precursors include, but are not limited to, include fatty acids, long chain fatty acids such as oleic acid, alkyl phosphonic acids, alkyl phosphinic acids, aromatic phosphonic acids, aromatic phosphinic acids, other organic inorganic oxyacids, etc. More particular examples include, but are not limited to, hexylphosphonic acid, tetradecylphosphonic acid, octylphosphonic acid, octadecylphosphonic acid, propylenediphosphonic acid, phenylphosphonic acid, phenylphosphonic acid, aminohexylphosphonic acid benzylphosphonic acid, 3,5-di-tert-butyl-4-hydroxybenzylphosphonic acid, etc. Other acid ligands can be readily ascertained by the skilled artisan.

The acid ligand can be added to the mixture as a single addition or as a series of periodic additions.

In one aspect, the acid ligand can be added to the mixture in a molar amount in a range from about ¼ of the number of moles of semiconductor nanocrystal cores included in the mixture (based on the semiconductor material composition of the core without regard to ligand(s)) to about three times the number of moles of semiconductor nanocrystal cores included in the mixture, e.g., the acid ligand can be added to the mixture in a molar amount from about 0.5 to about 2 times the number of moles of semiconductor nanocrystal cores included in the mixture can be desirable.

In another aspect, the amount of the acid ligand added to the mixture can be based on the amount of non-protonated surface modification agent added to the mixture. For example, the molar amount of non-protonated surface modification agent added can represent from about 30% to 220% of the molar amount of acid ligand added, e.g., from about 50% to 200% of the molar amount of acid ligand added, from about 100% to 150% of the molar amount of acid ligand added, about 120% of the molar amount of acid ligand added.

Other molar amounts of acid ligand may be determined by the skilled artisan, based on the present disclosure, to be useful or desirable.

After addition of the acid ligand to the mixture, the temperature can be reduced to a temperature that is lower than the reaction temperature. For example, such lower temperature can be selected for annealing the overcoated semiconductor nanocrystals.

As described above, optionally, one or more non-acid ligands can be further included in the mixture before addition of the precursors, during addition of the precursors, and/or following addition of the precursors.

Such non-acid ligands can be derived from a coordinating solvent that may be included in the mixture during growth of the shell. Alternatively, non-acid ligands can be added to the mixture or ligands can be derived from a reagent or precursor included in the mixture for forming the shell. In certain embodiments, semiconductor nanocrystals can include one or more different ligands attached to an outer surface.

Examples of non-acid ligands that can optionally be included in the mixture of the method described herein before or during addition of the one or more shell precursors include alkyl phosphines, alkyl phosphine oxides, pyridines, furans, and amines. More specific examples include, but are not limited to, pyridine, tri-n-octyl phosphine (TOP), tri-n-octyl phosphine oxide (TOPO), primary amines, e.g., CH₃(CH₂)ₙNH₂ wherein n=4-19 (e.g., butylamine, pentylamine, hexylamine, heptylamine, octylamine, nonylamine, decylamine, undecylamine, dodecylamine, tridecylamine, tetradecylamine, pentadecylamine, hexadecylamine, heptadecylamine, octadecylamine, nonadecylamine, eicosylamine), secondary amines, e.g., (CH₃(CH₂)ₙ)₂NH wherein n=3-11 (e.g., dibutylamine, dipentylamine, dihexylamine, diheptylamine, dioctylamine, dinonylamine, didecylamine, didundecylamine, didodecylamine), etc. In certain embodiments, an amine comprises, for example, but not limited to, decylamine, octadecylamine, and oleylamine. Other nonlimiting examples include 2-ethylhexyl amine and ethanolamine. An amine compound can also comprise a phenyl alkyl amine (e.g., but not limited to, phenylbutyl amine, 4-phenylbutyl amine, 3,3-diphenylpropylamine, (2,3-diphenylpropyl)amine, or an aliphatic amine Other non-acid ligands can be readily ascertained by the skilled artisan.

According to a certain aspect, reaction mixtures described herein may be degassed. Reagents, components or solvents may be placed in a reaction vessel and degassed to the extent that oxygen is removed to create an oxygen-free condition. Additional reagents, components or solvents may be added to the reaction vessel under oxygen-free conditions. According to one aspect, one or more reagents, components or solvents of the reaction mixture are degassed and the one or more reagents, components or solvents are combined together. According to one aspect, all reagents, components or solvents of the reaction mixture are degassed and are combined together. According to one aspect, a degassed or oxygen-free reaction mixture is provided for producing semiconductor nanocrystals. According to one aspect, the reaction mixture is under oxygen-free conditions. An oxygen-free condition refers to a condition or an atmosphere where oxygen is substantially or completely absent. An oxygen-free condition can be provided by a nitrogen atmosphere or other inert gas atmosphere where oxygen is absent or substantially absent. In addition, an oxygen-free condition can be provided by removing oxygen from a reagent or reaction mixture such as by placing the reagent or reaction mixture under vacuum or forcing an inert gas through the reagent or reaction mixture to remove oxygen or both.

Semiconductor nanocrystals can be isolated or recovered, for example by precipitation with additional of butanol and methanol in a ratio of 1 to 1.5 to 0.5 v/v/v semiconductor nanocrystals stock solution to butanol to methanol, and then placed into a non-coordinating solvent in a reaction vessel at a temperature of between about 200° C. to about 250° C., between about 210° C. to about 240° C. or between about 220° C. to about 240° C. Non-coordinating solvents include 1-decene, 1-dodecene, 1-tetradecene, 1-hexadecene, 1-octadecene, 1-icosene and 1-docosene and the like.

The narrow size distribution of the semiconductor nanocrystals (including, e.g., semiconductor nanocrystals) allows the possibility of light emission in narrow spectral widths. Monodisperse semiconductor nanocrystals have been described in detail in Murray et al. (J. Am. Chem. Soc., 115:8706 (1993)) hereby incorporated herein by reference in its entirety.

Size distribution during the reaction process can be estimated by monitoring the absorption or emission line widths of the particles. Modification of the reaction temperature in response to changes in the absorption spectrum of the particles allows the maintenance of a sharp particle size distribution during growth. Reactants can be added to the nucleation solution during crystal growth to grow larger crystals. For example, for CdSe and CdTe, by stopping growth at a particular semiconductor nanocrystal average diameter and choosing the proper composition of the semiconducting material, the emission spectra of the semiconductor nanocrystals can be tuned continuously over the wavelength range of 300 nm to 5 microns, or from 400 nm to 800 nm.

The particle size distribution of the semiconductor nanocrystals (including, e.g., semiconductor nanocrystals) can be further refined by size selective precipitation with a poor solvent for the semiconductor nanocrystals, such as methanol/butanol. For example, semiconductor nanocrystals can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected semiconductor nanocrystal (e.g., semiconductor nanocrystal) population preferably has no more than a 15% rms deviation from mean diameter, more preferably 10% rms deviation or less, and most preferably 5% rms deviation or less.

The emission from a semiconductor nanocrystal capable of emitting light can be a narrow Gaussian emission band that can be tuned through the complete wavelength range of the ultraviolet, visible, or infra-red regions of the spectrum by varying the size of the semiconductor nanocrystal, the composition of the semiconductor nanocrystal, or both. For example, a semiconductor nanocrystals comprising CdSe can be tuned in the visible region; a semiconductor nanocrystal comprising InAs can be tuned in the infra-red region. The narrow size distribution of a population of semiconductor nanocrystals capable of emitting light can result in emission of light in a narrow spectral range. The population can be monodisperse and preferably exhibits less than a 15% rms (root-mean-square) deviation in diameter of such semiconductor nanocrystals, more preferably less than 10%, most preferably less than 5%. Spectral emissions in a narrow range of no greater than about 75 nm, preferably no greater than about 60 nm, more preferably no greater than about 40 nm, and most preferably no greater than about 30 nm full width at half max (FWHM) for such semiconductor nanocrystals that emit in the visible can be observed. IR-emitting semiconductor nanocrystals can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of the light-emitting semiconductor nanocrystal diameters decreases.

Semiconductor nanocrystals can have emission quantum efficiencies such as between 0% to greater than 95%, for example in solution, such as greater than 10%, 20%, 30%, 40%, 50%, 60%, 70%, 80%, or 90%.

The present invention will be further clarified by the following non-limiting example(s), which is(are) intended to be exemplary of the present invention.

### Core Preparation

### Preparation of Semiconductor Nanocrystal Cores:

2.932 g of zinc stearate, 0.49 g of zinc acetate, 5.75 g of myristic acid and 230 g of squalane were placed into a 1L four-neck glass reactor equipped with a condenser and stirred to form a suspension. 13.1 g of trimethylindium and 50 g of squalane were placed into a 250mL flask. The mixture was warmed up to 70° C. to form a milky solution and then transferred into the suspension of the 1L reactor. The temperature controller of the reactor was set to 275° C. The suspension became a clear solution while heated up to 110° C. In the meantime, a solution of 1.334g of dodecanethiol (DDT) and 1.35 g of tris(trimethylsilyl)phosphine (P(TMS)₃) in 40 g of squalane was prepared and placed in a 60 mL syringe. When the solution in the reactor reached 275° C., the DDT/P(TMS)₃ solution was swiftly injected into the reactor. The reaction was then allowed to run for 3 hours. In the end, the solution was cooled down to 100° C. with an air gun. The InZnPS semiconductor nanocrystal cores prepared were isolated by known techniques and dispersed in hexane. Core characterization: Absorbance/Emission/FWHM (nm) of 461/503/46.

### EXAMPLE 1

### Overcooling of Semiconductor Nanocrystal Core:

Ortho-terphenyl (8 g) was weighed into a four-neck 50 mL round bottom flask, equipped with a stirring bar, and air condenser, and a thermal coupler. Squalene (2 mL) was then added. The temperature of the squalene was raised to 90° C. under vacuum to degas for 2 hours. After refilling the flaks with nitrogen, InZnPS cores dispersed in hexane (13.23 mmol InZnPS cores in 3,48 mL) (prepared generally as described in the above CORE PREPARATION description) were added via syringe. The flask then switched to vacuum again for 1.5 hours to completely remove the solvent. After switch back to nitrogen, phenylbutylamine (0.5 mL) was added followed by the addition of dodecyl acetate (1.14 mL), Meanwhile diethylzinc (ZnEt₂) (155 mg in 4 mL squalene) and bis(trimethylsilyl)sulfide ((TMS)₂S) (224 mg in 4 mL squalene) were mixed separately in separate syringes and loaded on infusion pump. The temperature for the reaction was set at 240° C. When it reached 150° C., the infusion of Zn and S precursors was started with a rate of 2 mL/hour. Benzylphosphonic acid (0.615 g) was dissolved in 4 mL N-dodecylpyrrolidone (NDP) and loaded on a separate pump. After twenty (20) minutes of infusing the Zn and S precursors, infusion of the solution of benzylphosphonic acid in NDP was started at a rate of 2.4 mL/hour. After the addition of the benzylphosphonic acid solution, the mixture was cooled to 140° C. overnight and then transferred into glovebox. The ZnS overcoated InZnPS semiconductor nanocrystals were isolated by precipitation by addition of isopropyl alcohol (IPA) and butanol/IPA/hexane (1:1:1) and then dispersed in toluene for characterization.

The ZnS overcoated InZnPS semiconductor nanocrystals of Example 1 exhibited a center peak emission at 530 nm, a full width at half maximum of 53 nm, absorbance at 471 nm, and a solution quantum yield of 60%.

### COMPARATIVE EXAMPLE 1

ZnS overcoated InZnPS semiconductor nanocrystals prepared generally in accordance with the procedure of Example 1, but without the addition of the non-protonated surface modification agent of dodecyl acetate.

The ZnS overcoated InZnPS semiconductor nanocrystals of Comparative Example 1 exhibited a center peak emission at 532 nm, a full width at half maximum of 56 nm, absorbance at 474 nm, and a solution quantum yield of 49%.

Semiconductor nanocrystals produced according to the present invention may be used in various applications. According to one aspect, semiconductor nanocrystals produced according to the methods described herein may be used in photoluminescent (PL) applications where semiconductor nanocrystal materials are excited optically and the optical excitation is downconverted via emission from the QDs. According to this aspect, exemplary applications include devices or systems where an LED light source is used, for example solid-state lighting, LED Backlights (LED-BLU), Liquid Crystal Displays (LCD) and the like. According to an additional aspect, semiconductor nanocrystals produced according to the methods described herein may be used in a device or system where a light source is downconverted to other wavelengths (e.g. solar concentrators or downconverters where sunlight is converted to specific wavelengths tuned to the highest efficiency window of the solar cells used in the system. Additional applications include plasma based systems where high energy plasma emission can excite a semiconductor nanocrystals downconverter, taggants, bio-labeling or imaging application, and barcoding or security/covert labeling applications. According to an additional aspect, semiconductor nanocrystals produced according to the present invention may be used in electroluminescent (EL) applications where semiconductor nanocrystals are excited electrically and the excitation results in emission from the semiconductor nanocrystals. According to this aspect, exemplary applications include direct charge injection into the semiconductor nanocrystals generating semiconductor nanocrystal excited states and subsequent semiconductor nanocrystal emission, energy transfer from other semiconductor materials within the device to the semiconductor nanocrystals, generating an excited state and subsequent semiconductor nanocrystal emission and the like. According to an additional aspect, semiconductor nanocrystals produced according to the present invention may be used in photovoltaic (PV) applications where the semiconductor nanocrystal materials are excited optically and the excitation results in current generation and/or a voltage due to carrier extraction from the semiconductor nanocrystals.

Additional information that may be useful in connection with the present disclosure and the inventions described herein is included in International Application No. PCT/US2008/10651 of Breen et al, filed 12 Sep. 2008, entitled “Functionalized Nanoparticles And Method”; and International Application No. PCT/US2007/024320 of Clough et al, filed 21 November 2007, entitled “Nanocrystals Including A Group IIIa Element And A Group Va Element, Method, Composition, Device And Other Products”; International Application No. PCT/US2012/038198, filed May 16, 2012, entitled “Method for Preparing Semiconductor Nanocrystals”; International Application No. PCT/US2009/002789 of Coe-Sullivan et al, filed 6 May 2009, entitled : “Solid State Lighting Devices Including Quantum Confined Semiconductor Nanoparticles, An Optical Component For A Solid State Light Device, And Methods”, and International Application No. PCT/US2011/047284 of Sadasivan et al, filed 10 Aug. 2011 entitled “Quantum Dot Based Lighting” each of the foregoing being hereby incorporated herein by reference in its entirety.

Solid state external quantum efficiency” (also referred to herein as “EQE” or “solid state photoluminescent efficiency”) can be measured in a 12″ integrating sphere using a NIST traceable calibrated light source, using the method developed by de Mello et al., Advanced Materials 9(3):230 (1997), which is hereby incorporated by reference. Such measurements can also be made with a QEMS from LabSphere (which utilizes a 4 inch sphere; e.g. QEMS-2000: World Wide Website laser2000.nl/upload/documenten/fop_{—}21-en2.pdf).

As used herein, the singular forms “a”, “an” and “the” include plural unless the context clearly dictates otherwise. Thus, for example, reference to an emissive material includes reference to one or more of such materials.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein, It is intended that the present specification and examples be considered as exemplary only with a true scope and spirit of the invention being indicated by the following claims and equivalents thereof.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A method for preparing semiconductor nanocrystals, the method comprising: adding a non-protonated surface modification agent to semiconductor nanocrystal cores in a liquid medium to form a mixture; adding one or more precursors for forming a shell comprising a semiconductor material to the mixture under conditions for forming the shell over at least a portion of an outer surface of the cores, and adding an acid ligand to the mixture after addition of at least a portion of the one or more precursors.

2. A method in accordance with claim 1 wherein one or more non-acid ligands are further included in the mixture before addition of the precursors.

3. A method in accordance with claim 1 wherein one or more non-acid ligands are added to the mixture during addition of the precursors.

4. A method in accordance with claim 1 wherein one or more non-acid ligand sources are added to the mixture following addition of the precursors.

5. A method in accordance with claim 1 wherein the non-protonated surface modification agent comprises a carboxylic acid ester.

6. A method in accordance with claim 1 wherein the non-protonated surface modification agent comprises a carboxylic acid anhydride.

7. A method in accordance with claim 1 wherein the non-protonated surface modification agent comprises a phosphonic acid ester.

8. A method in accordance with claim 1 wherein the non-protonated surface modification agent comprises a phosphonic acid anhydride.

9. A method in accordance with claim 1 wherein the mixture is heated at a reaction temperature.

10. A method in accordance with claim 9 wherein the reaction temperature is greater than 200° C.

11. A method in accordance with claim 1 wherein the temperature of the mixture is reduced after completing addition of the acid ligand.

12. A method in accordance with claim 1 wherein the presence of the non-protonated surface modification agent in the mixture results in a blue shift of the emission wavelength of the semiconductor nanocrystals less than 20 nm.

13. A method in accordance with claim 1 wherein the presence of the non-protonated surface modification agent in the mixture results in a blue shift of the emission wavelength of the semiconductor nanocrystals less than 15 nm.

14. A method in accordance with claim 1 wherein the presence of the non-protonated surface modification agent in the mixture results in a blue shift of the emission wavelength of the semiconductor nanocrystals less than 10 nm.

15. A method in accordance with claim 1 wherein the liquid medium is non-protic.

16. A method in accordance with claim 1 wherein the mixture is a non-protic environment when the addition of the one or more precursors is initiated.

17. A method in accordance with claim 1 wherein addition of the acid ligand is initiated after completion of the addition of the one or more precursors.

18. A method for preparing semiconductor nanocrystals, comprising: adding a non-protonated surface modification agent to semiconductor nanocrystal cores comprising a first semiconductor material comprising one or more Group IIIA elements and one or more Group VA elements in a non-protic liquid medium to form a mixture; adding one or more precursors for forming a shell comprising a second semiconductor material comprising one or more Group IIA elements and one or more Group VIA elements to the mixture under conditions for forming the shell over at least a portion of an outer surface of the cores, and adding an acid ligand to the mixture after addition of at least a portion of the one or more precursors.

19-24. (canceled)

25. A method in accordance with claim 18 wherein the mixture is a non-protic environment when the addition of the one or more precursors is initiated,

26. A method in accordance with claim 18 wherein the first semiconductor material comprises indium, zinc, phosphorus, and sulfur.
